(19) United States
(12) Patent Application Publication
(10) Pub. No.: US 2009/0091028 A1
(43) Pub. Date: Apr. 9, 2009

(54) SEMICONDUCTOR DEVICE AND METHOD OF BUMP FORMATION

(75) Inventors: Chiu-Shun Lin, Tainan County (TW); Chia-Hui Wu, Tainan County (TW); Wen-Chieh Tu, Tainan County (TW)

Correspondence Address: J C PATENTS, INC., 4 VENTURE, SUITE 250, IRVINE, CA, 92618, US

(73) Assignee: HIMAX TECHNOLOGIES LIMITED, Tainan County (TW)

(21) Appl. No.: 12/110,868

(22) Filed: Apr. 28, 2008

Related U.S. Application Data
(60) Provisional application No. 60/977,088, filed on Oct. 3, 2007.

(51) Int. Cl. H01L 23/482; H01L 21/44

(52) U.S. Cl. 257/737; 438/613; 257/E23.015; 257/E21.476

(57) ABSTRACT

A semiconductor device including a semiconductor substrate, a contact pad, a passivation layer, a bump, and a seeding layer is provided. The semiconductor substrate has an active surface. The contact pad is disposed on the active surface. The passivation layer is disposed on the active surface and exposes a central part of the contact pad. The seeding layer is disposed on the exposed central part of the contact pad. The bump has a top surface, a bottom surface opposite to the top surface, and a side surface connecting the top surface and the bottom surface. The bump is disposed on the seeding layer. The bump is placed in contact with the seeding layer by the bottom surface and by part of the side surface.

### CROSS-REFERENCE TO RELATED APPLICATION

This application claims the priority benefit of U.S. prior-filed provisional application Ser. No. 60/977,088, filed on Oct. 3, 2007. The entirety of the above-mentioned patent application is hereby incorporated by reference herein and made a part of specification.

### BACKGROUND OF THE INVENTION

1. Field of the Invention

The present invention generally relates to an electronic device and a process thereof and, in particular, to a semiconductor device and a method of bump formation.

2. Description of Related Art

The flip chip technology is a packaging technology frequently applied in the chip scale packaging (CSP). The flip chip technology diminishes the packaging area since it employs area array for the disposition of contact pads on a chip, and it shortens the path of signal transmission since it employs bumps to electrically connect the chip with a carrier.

Generally speaking, there is a passivation layer covering the surface of the chip and exposing aluminium (Al) contact pads of the chip. When the flip chip technology is proceeded, a under bump metal (UBM) is formed on the passivation layer and the contact pads first. Next, a photoresist layer is formed on the UBM, but the photoresist layer exposes the part of the UBM which is located over the contact pads. photoresist layer exposes the part of the UBM which is located over the contact pads. Gold (Au) bumps are then formed on the part of the UBM located over the contact pads. After that, the photoresist layer is stripped. Subsequently, the other part of the UBM is etched out which is not located between the Au bumps and the Al contact pads. To prevent the over-etching of the UBM between the bumps and the Al contact pads, the Au bumps have to overlap the passivation layer to an enough degree, which makes the roughness of the top surface of the Au bump increases. For example, the edge of the top surface of the Au bump protrudes away from the Al contact pad. When the Au bumps is bonded to the carrier through an anisotropic conductive film (ACF), the increased roughness of the top surface makes some portions of the Au bump unable to compress the conductive particles in the ACF, thus reducing the conductivity between the chip and the carrier.

### SUMMARY OF THE INVENTION

Accordingly, the present invention is directed to a semiconductor device the bump of which has a flatter surface.

The present invention is directed to a method of bump formation which forms a bump with a flatter surface on a semiconductor substrate.

According to an embodiment of the present invention, a semiconductor device including a semiconductor substrate, a contact pad, a passivation layer, a bump, and a seeding layer is provided. The semiconductor substrate has an active surface. The contact pad is disposed on the active surface. The passivation layer is disposed on the active surface and exposes a central part of the contact pad. The seeding layer is disposed on the exposed central part of the contact pad. The bump has a top surface, a bottom surface opposite to the top surface, and a side surface connecting the top surface and the bottom surface. The bump is disposed on the seeding layer. The bump is placed in contact with the seeding layer by the bottom surface and by part of the side surface.

According to another embodiment of the present invention, a method of bump formation including the following steps is provided. First, a semiconductor substrate having an active surface is provided, in which a contact pad is disposed on the active surface, and a passivation layer is disposed on the active surface and has an opening exposing the contact pad. Next, a first photoresist layer is formed on the passivation layer, in which the first photoresist layer has a top surface and at least one side wall connected with the top surface, and the side wall defines an opening exposing a part of the contact pad. After that, a seeding layer is formed on the top surface, the side wall, and the contact pad. Subsequently, a second photoresist layer is formed on a part of the seeding layer located on the top surface, and the other part of the seeding layer inside the opening is exposed. Then, a bump is formed at the opening and on the seeding layer. Afterward, the second photoresist layer is removed. Next, the part of the seeding layer on the top surface is removed. Subsequently, the first photoresist layer is removed.

In the semiconductor device according to an embodiment of the present invention, the bump is placed in contact with the seeding layer by part of the side surface. This is able to prevent the over-etching of the seeding layer between the bump and the contact pad in the fabrication process, such that the bump is not necessary to overlap the passivation layer to an enough degree to prevent the over-etching, which enables the bump to have a flatter surface. Additionally, in the method of bump formation according to an embodiment of the present invention, when the seeding layer is etched, the first photoresist layer below the seeding layer still exists and surrounds the bump, which prevents the over-etching of the seeding layer between the bump and the contact pad. In this way, the bump is not necessary to overlap the passivation layer to an enough degree to prevent the over-etching, such that the bump is able to have a flatter surface.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic cross-sectional view of a semiconductor device according to an embodiment of the present invention.

FIG. 2 is a schematic cross-sectional view of a semiconductor device according to another embodiment of the present invention.

FIG. 3 is a schematic cross-sectional view of a semiconductor device according to yet another embodiment of the present invention.

FIGS. 4A through 4H are schematic views showing the steps of a method of bump formation according to an embodiment of the present invention.

FIG. 5 is a schematic view showing a step of a method of bump formation according to another embodiment of the present invention.

FIG. 6 is a schematic view showing a step of a method of bump formation according to yet another embodiment of the present invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

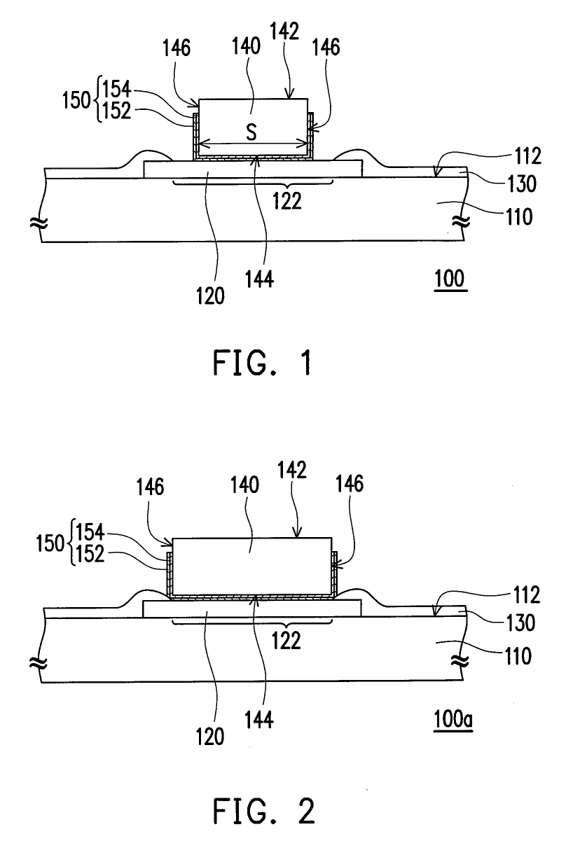

FIG. 1 is a schematic cross-sectional view of a semiconductor device according to an embodiment of the present invention. Referring to FIG. 1, the semiconductor device 100 of the present embodiment includes a semiconductor substrate 110, a plurality of contact pads 120, a passivation layer 130, a plurality of bumps 140, and a plurality of seeding layers 150. However, a contact pad 120, a bump 140, and a seeding layer 150 are shown in FIG. 1 for representation. The semiconductor substrate 110 has an active surface 112. Each contact pad 120 is disposed on the active surface 112, and is, for example, a metal pad. In the present embodiment, the semiconductor substrate 110 is, for example, a chip which includes an integrated circuitry electrically connected to the contact pads 120. The passivation layer 130 is disposed on the active surface 112 and exposes a central part 122 of each contact pad 120. The passivation layer is, for example, an insulation layer.

The seeding layer 150 is disposed on the exposed central part 122 of the contact pad 120. The bump 140 has a top surface 142, a bottom surface 144 opposite to the top surface 142, and at least one side surface 146 connecting the top surface 142 and the bottom surface 144. The bump 140 is, for example, a metal bump. Additionally, the bump 140 is disposed on the seeding layer 150. The bump 140 is placed in contact with the seeding layer 150 by the bottom surface 144 and by part of the side surface 146. In the present embodiment, the seeding layer 150 is an under bump metal (UBM) which may be a multilayer. For example, when the bump 140 is an Au bump and the contact pad 120 is an Al pad, the UBM includes a titanium tungsten (TiW) layer 152 formed on the Al pad and an Au layer 154 formed between the TiW layer and the bump 140.

In the semiconductor device 100 of the present embodiment, the bump 140 is placed in contact with the seeding layer 150 by part of the side surface 146. This is able to prevent the over-etching of the seeding layer 150 between the bump 140 and the contact pad 120 in the fabrication process, such that the bump 140 is not necessary to overlap the passivation layer 130 to an enough degree to prevent the over-etching, which enables the bump 140 to have a flatter top surface 142. In the present embodiment, the seeding layer 150 is not directly coupled to the passivation layer 130. That is to say, the bump 140 does not overlap the passivation layer 130, such that the roughness of the top surface 142 of the bump 140 may be less than 1 micron. In this way, the conductivity between the semiconductor device 100 and a carrier (not shown) to which the bump 140 is bonded is better. For example, this is because the flatter top surface 142 may uniformly compress the conductive particles in an ACF which bonds the bump 140 to the carrier. In addition, since the bump 140 is not necessary to overlap the passivation layer 130, the width S of the bump 140 may be smaller, which increases the layout flexibility of the semiconductor device 100 and the carrier.

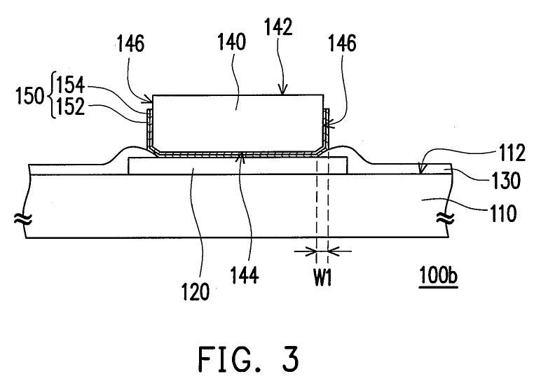

FIG. 2 is a schematic cross-sectional view of a semiconductor device according to another embodiment of the present invention. The semiconductor device 100a of the present embodiment is similar to the above semiconductor device 100 in FIG. 1 except for the differences as follows. In the semiconductor device 100a, the seeding layer 150 covers the central part 122 of the contact pad 120, and the bump 140 does just not overlap the passivation layer 130. The semiconductor device 100a has similar advantages as those of the above semiconductor 100 which will not be repeated herein.

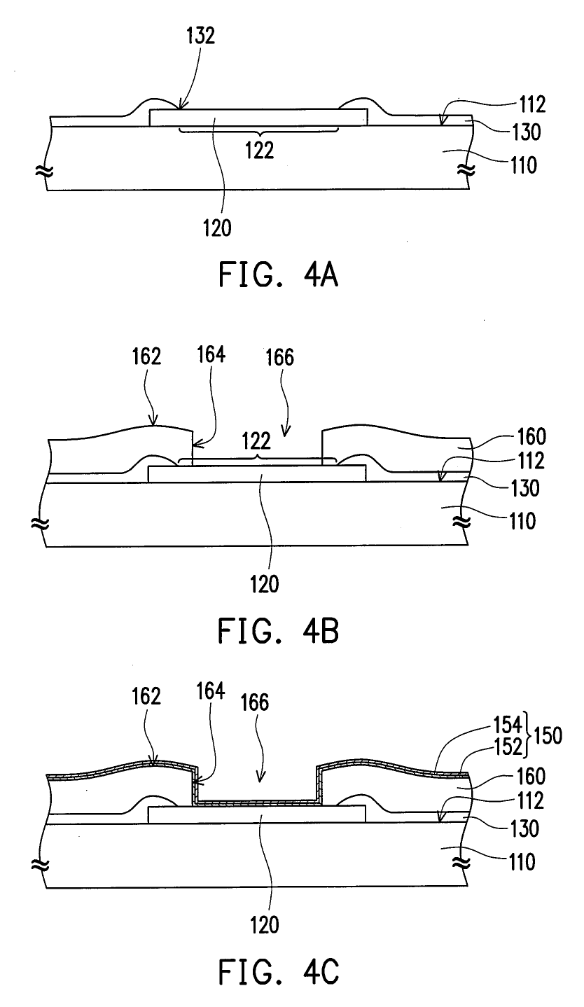

FIG. 3 is a schematic cross-sectional view of a semiconductor device according to yet another embodiment of the present invention. The semiconductor device 100b of the present embodiment is similar to the above semiconductor device 100 in FIG. 1 except for the differences as follows. In the semiconductor device 100b, the seeding layer 150 covers the central part 122 of the contact pad 120 and the passivation 130 layer surrounding the central part 122 of the contact pad 120. In the present embodiment, the passivation layer 130 under the seeding layer 150 is less than 3 microns. In other words, the width W1 shown in FIG. 3 is less than 3 microns. That is to say, the bump 140 overlaps the passivation layer 130 slightly, such that the top surface 142 of the bump 140 is still flatter than the conventional bump. Therefore, the semiconductor device 100b still has similar advantages as those of the above semiconductor 100 which will not be repeated herein.

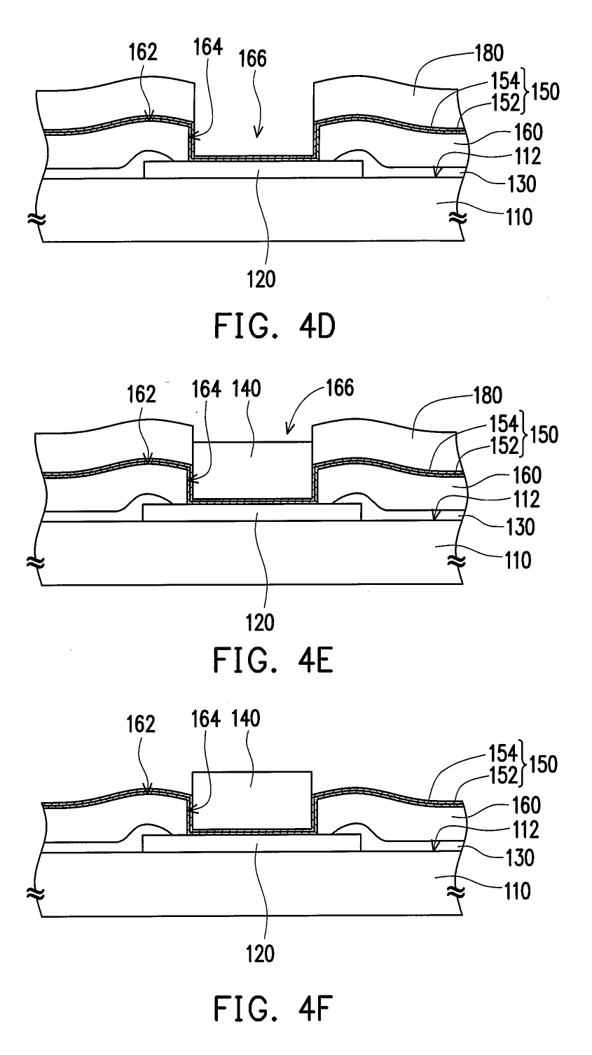

FIGS. 4A through 4H are schematic views showing the steps of a method of bump formation according to an embodiment of the present invention. The method of bump formation may be applied to fabricate the above semiconductor device 100 in FIG. 1, and includes the following steps. First, referring to FIG. 4A, the semiconductor substrate 110 having the active surface 112 is provided, in which the contact pad 120 is disposed on the active surface 112, and the passivation layer 130 is disposed on the active surface 112 and has an opening 132 exposing the contact pad 120. In the present embodiment, the opening 132 of the passivation layer 130 exposes a central part 122 of the contact pad 120. Next, referring to FIG. 4B, a first photoresist layer 160 is formed on the passivation layer 130, in which the first photoresist layer 160 has a top surface 162 and at least one side wall 164 connected with the top surface 162, and the side wall 164 defines an opening 166 exposing a part of the contact pad 120. In the present embodiment, the first photoresist layer 160 is formed by photolithography. Additionally, in the present embodiment, the first photoresist layer 160 covers the edge of the central part 122 of the contact pad 120. After that, referring to FIG. 4C, a seeding layer 150 is formed on the top surface 162, the side wall 164, and the contact pad 120. In the present embodiment, the material of the seeding layer 150 is a UBM like the seeding layer 150 in FIG. 1. Subsequently, referring to FIG. 4D, a second photoresist layer 180 is formed on the part of the seeding layer 150 located on the top surface 162, and the other part of the seeding layer 150 inside the opening 166 is exposed. In the present embodiment, the second photoresist layer 180 may also be formed by photolithography. Then, referring to FIG. 4E, the bump 140 is formed at the opening 166 and on the seeding layer 150. In the present embodiment, the bump 140 is formed by plating. Afterward, referring to FIG. 4F, the second photoresist layer 180 is removed. Next, referring to FIG. 4G, the part of the seeding layer 150 on the top surface 162 is removed. In the present embodiment, the seeding layer 150 on the top surface 162 is removed by etching. More particularly, in the present embodiment, the Au layer 154 of the seeding layer 150 is etched by potassium iodide (KI) solution, and the TiW layer 152 of the seeding layer 150 is etched by hydrogen peroxide (H₂O₂) solution, for example. Subsequently, referring to FIG. 4H, the first photoresist layer 160 is removed, and the method of bump formation of the present embodiment is accomplished.

In the method of bump formation of the present embodiment, when the seeding layer 150 is etched, the first photoresist layer 160 below the seeding layer still exists and surrounds the bump 140, which prevents the over-etching of the seeding layer 150 between the bump 140 and the contact pad 120. In this way, the bump 140 is not necessary to overlap the passivation layer 130 to an enough degree to prevent the over-etching, such that the bump 140 is able to have a flatter top surface 142.

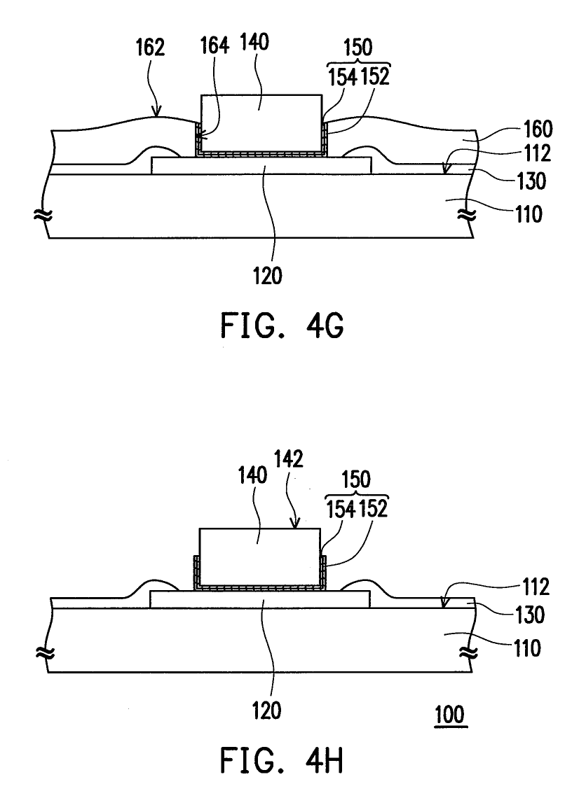

FIG. 5 is a schematic view showing a step of a method of bump formation according to another embodiment of the present invention. The method of bump formation is similar to the above method of bump formation shown in FIGS. 4A through 4H except for the differences as follows. Referring to FIG. 5, in the present embodiment, when the first photoresist layer 160 is formed, the side wall 164 of the first photoresist layer 160 is substantially located at a boundary B between the central part 122 of the contact pad 120 and the passivation layer 130. The method of bump formation in the present embodiment forms the bump 140 in FIG. 2.

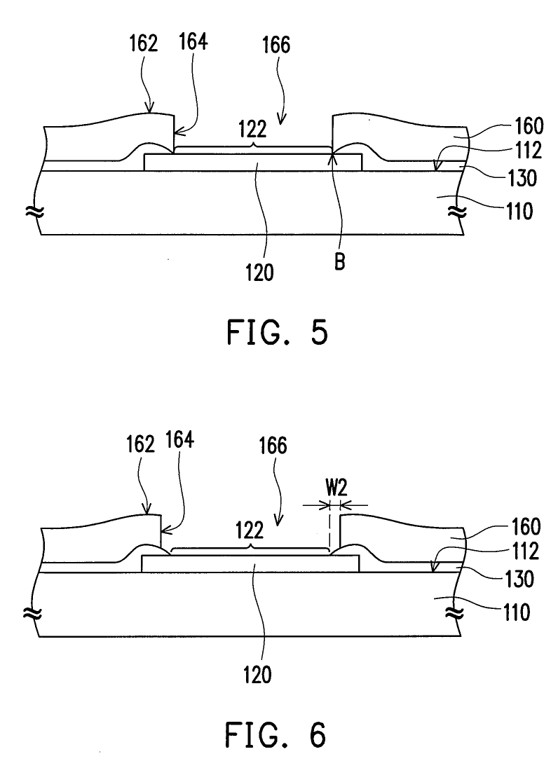

FIG. 6 is a schematic view showing a step of a method of bump formation according to yet another embodiment of the present invention. The method of bump formation is similar to the above method of bump formation shown in FIGS. 4A through 4H except for the differences as follows. Referring to FIG. 6, in the present embodiment, when the first photoresist layer 160 is formed, the opening 166 defined by the side wall 164 of the first photoresist layer 160 exposes a part of the passivation layer 130 around the central part 122 less than 3 microns. In other words, the width W2 shown in FIG. 6 is less than 3 microns. The method of bump formation in the present embodiment forms the bump 140 in FIG. 3.

To sum up, in the semiconductor device according to an embodiment of the present invention, the bump is placed in contact with the seeding layer by part of the side surface. This is able to prevent the over-etching of the seeding layer between the bump and the contact pad in the fabrication process, such that the bump is not necessary to overlap the passivation layer to an enough degree to prevent the over-etching, which enables the bump to have a flatter surface. In this way, the conductivity between the semiconductor device and a carrier to which the bump is bonded is better. In addition, since the bump is not necessary to overlap the passivation layer, the width of the bump may be smaller, which increases the layout flexibility of the semiconductor device or the carrier.

Moreover, in the method of bump formation according to an embodiment of the present invention, when the seeding layer is etched, the first photoresist layer below the seeding layer still exists and surrounds the bump, which prevents the over-etching of the seeding layer between the bump and the contact pad. In this way, the bump is not necessary to overlap the passivation layer to an enough degree to prevent the over-etching, such that the bump is able to have a flatter surface.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A semiconductor device, comprising:
a semiconductor substrate, having an active surface;
a contact pad, disposed on the active surface;
a passivation layer, disposed on the active surface and exposing a central part of the contact pad;
a seeding layer, disposed on the exposed central part of the contact pad; and
a bump, having a top surface, a bottom surface opposite to the top surface, and a side surface connecting the top surface and the bottom surface, the bump being disposed on the seeding layer,
wherein the bump is placed in contact with the seeding layer by the bottom surface and by part of the side surface.

2. The semiconductor device according to claim 1, wherein the seeding layer is not directly coupled to the passivation layer.

3. The semiconductor device according to claim 1, wherein the seeding layer covers the central part of the contact pad and the passivation layer surrounding the central part of the contact pad.

4. The semiconductor device according to claim 3, wherein the passivation layer under the seeding layer is less than 3 microns.

5. The semiconductor device according to claim 1, wherein the semiconductor substrate comprises an integrated circuitry.

6. The semiconductor device according to claim 1, wherein the contact pad is a metal pad.

7. The semiconductor device according to claim 1, wherein the bump is a metal bump.

8. The semiconductor device according to claim 1, wherein the seeding layer is an under bump metal.

9. A method of bump formation, comprising:
providing a semiconductor substrate having an active surface, wherein a contact pad is disposed on the active surface, and a passivation layer is disposed on the active surface and has an opening exposing the contact pad;
forming a first photoresist layer on the passivation layer, wherein the first photoresist layer has a top surface and at least one side wall connected with the top surface, and the side wall defines an opening exposing a part of the contact pad;
forming a seeding layer on the top surface, the side wall, and the contact pad;
forming a second photoresist layer on a part of the seeding layer located on the top surface and exposing the other part of the seeding layer inside the opening;
forming a bump at the opening and on the seeding layer;
removing the second photoresist layer;
removing the part of the seeding layer on the top surface; and
removing the first photoresist layer.

10. The method of bump formation according to claim 9, wherein the opening of the passivation layer exposes a central part of the contact pad.

11. The method of bump formation according to claim 10, wherein at the first photoresist layer forming step, the first photoresist layer covers an edge of the central part of the contact pad.

12. The method of bump formation according to claim 10, wherein at the first photoresist layer forming step, the opening defined by the side wall of the first photoresist layer exposes a part of the passivation layer around the central part less than 3 microns.

13. The method of bump formation according to claim 10, wherein at the first photoresist layer forming step, makes the side wall of the first photoresist layer substantially located at a boundary between the central part of the contact pad and the passivation layer.

14. The method of bump formation according to claim 9, wherein the bump forming step forms the bump by plating.

15. The method of bump formation according to claim 9, wherein the seeding layer removing step removes the seeding layer on the top surface by etching.
